(19) United States
(12) Patent Application Publication
(10) Pub. No.: US 2014/0014644 A1
(43) Pub. Date: Jan. 16, 2014

(54) Heating Device

(71) Applicants: Hironori Akiba, Ota-ku (JP); Kazuhiko Kubota, Naka-gun (JP); Tsutomu Hatanaka, Hiratsuka-shi (JP); Yuichi Sakai, Koshi-shi (JP); Akira Yonemizu, Koshi-shi (JP); Kazuhiko Ooshima, Koshi-shi (JP)

(72) Inventors: Hironori Akiba, Ota-ku (JP); Kazuhiko Kubota, Naka-gun (JP); Tsutomu Hatanaka, Hiratsuka-shi (JP); Yuichi Sakai, Koshi-shi (JP); Akira Yonemizu, Koshi-shi (JP); Kazuhiko Ooshima, Koshi-shi (JP)

(73) Assignees: TOKYO ELECTRON LIMITED, Minato-ku, Tokyo (JP); KOMATSU LTD., Minato-ku, Tokyo (JP)

(21) Appl. No.: 14/008,373

(22) PCT Filed: Mar. 28, 2012
(86) PCT No.: PCT/JP2012/058074

§ 371 Date: Sep. 27, 2013

(30) Foreign Application Priority Data
Mar. 28, 2011 (JP) 2011-071244

(51) Int. Cl. H01L 21/02

(52) U.S. Cl. CPC H01L 21/02002
USPC 219/444.1

(57) ABSTRACT

A heating device includes a substrate in a form of a face plate that is positioned above a base plate, on which a wafer is placed, and to which a film heater for heating wafer is provided, columns that are vertically provided between the base plate and the face plate and support the face plate, and tension members that pull the face plate toward the base plate. The columns and the tension members are positioned to support or pull at least a part of the face plate corresponding to a placement region of the wafer. Each of the tension members includes a shaft having an upper end locked by the face plate and a lower end penetrating the base plate and a coil spring that is positioned on the base plate and biases the lower end of the shaft downward.

### TECHNICAL FIELD

The present invention relates to a heating device, for instance, for heating a semiconductor wafer to a predetermined temperature.

### BACKGROUND ART

Typically, in a coater developer device used in a pattern printing step and the like of a semiconductor wafer, it is known that the wafer is heated by a heating device to a predetermined temperature (see, for instance, Patent Literature 1).

In the heating device of Patent Literature 1, a heat-generation resistor using a ceramic substrate is disposed. Electricity is supplied to the ceramic substrate to heat the ceramic substrate. An outer circumference of such a ceramic substrate is supported by a support body below the ceramic substrate while the ceramic substrate is pressed onto the support body by a bias force from above.

The supported part of the ceramic substrate is configured such that a bolt is vertically provided to the support body below the ceramic substrate while penetrating the ceramic substrate, and the bolt projecting beyond an upper surface of the ceramic substrate is inserted into a coil spring to hold the coil spring between the upper surface of the ceramic substrate and a nut screwed to an upper part of the bolt.

With this arrangement, since the ceramic substrate is biased toward the support body below the ceramic substrate by the coil spring, deformation of the support body can be absorbed by the coil spring, so that the ceramic substrate can be prevented from being bent.

### CITATION LIST

### Patent Literature(s)

Patent Literature 1: JP-A-2004-95689

### SUMMARY OF THE INVENTION

### Problems to be Solved by the Invention

The ceramic substrate of Patent Literature 1 is unlikely to be thermally influenced, so that the ceramic substrate is not significantly bent due to heat generation. However, when the substrate is made of aluminum, since aluminum is a material having a smaller rigidity and a typically larger linear expansion coefficient than ceramic in the same size, the substrate is significantly bent around a part of the substrate retained by the support body in accordance with stretch of the substrate when heating a wafer, so that the wafer cannot be placed at a proper position on the substrate.

Particularly, when the substrate is made of aluminum, a time for raising or lowering a temperature of the substrate by heating aluminum or cooling the heated aluminum is defined as a down-time. In order to reduce the down-time, a heat capacity of the substrate needs to be reduced. However, when the heat capacity is decreased by thinning the aluminum substrate, the aluminum substrate is more significantly bent. For this reason, it is necessary to bias a wide region of the substrate, which includes not only an outer circumference but also a region corresponding to a placement surface of the wafer, toward the support body.

However, in Patent Literature 1, since a bolt is configured to project beyond an upper surface of the substrate, the wafer and the bolt interfere with each other in a placement region of the wafer, so that a wide region of the substrate cannot be biased downward.

Further, when the thickness of the substrate is reduced, the rigidity of the substrate is reduced to flex the substrate by a weight thereof, so that it may be impossible to place the wafer at a proper position on the substrate.

An object of the invention is to provide a heating device capable of reliably preventing a substrate from being flexed by a weight thereof and being bent by heat even when the substrate is significantly thinned and the temperature of the substrate is rapidly changed.

### Means for Solving the Problems

According to a first aspect of the invention, a heating device includes: a base plate; a face plate that is positioned above the base plate, on which a wafer is placed and to which a heating unit for heating the wafer is provided; a plurality of columns that are vertically provided between the base plate and the face plate and supports the face plate;

and a plurality of tension members that pull the face plate toward the base plate, in which the columns and the tension members are positioned to support and pull at least a portion of the face plate corresponding to a placement region of the wafer, and each of the tension members comprises: a shaft having an upper end locked by the face plate and a lower end penetrating the base plate; and a biasing unit that is positioned near the base plate and biases the lower end of the shaft downward.

In the heating device according to a second aspect of the invention, the columns and the tension members are positioned adjacent to each other.

In the heating device according to a third aspect of the invention, the face plate is provided with a plurality of wafer supporting units that support the wafer with a predetermined clearance between the wafer and an upper surface of the face plate, and the wafer supporting units are provided adjacent to both of the columns and the tension members.

In the heating device according to a fourth aspect of the invention, each of the tension members has a nut to be screwed onto a lower part of the shaft, and the biasing unit of each of the tension members is provided by a compression spring that is inserted onto the shaft and is interposed between the base plate and the nut.

According to a fifth aspect of the invention, a heating device includes: a base plate; a face plate that is positioned above the base plate and on which a wafer is placed; a cooling pipe that is interposed between the base plate and the face plate and through which refrigerant gas for cooling the face plate circulates; a heat-shield rectifying plate that is interposed between the base plate and the face plate to guide the refrigerant gas ejected through the cooling pipe and shields the base plate from radiation heat of the face plate; a wafer supporting unit that is provided in a manner to project beyond an upper surface of the face plate; a heating unit that is provided to the face plate and is adapted to heat the wafer; a terminal block that is attached to the base plate and to which an electricity-supply terminal provided to the heating unit and a wire from an external power source are connected; a plurality of columns that are vertically provided between the base plate and the face plate and supports the face plate; and a plurality of tension members that pull the face plate toward the base plate, in which the columns and the tension members are positioned to support and pull at least a portion of the face plate corresponding to a placement region of the wafer, and each of the tension members comprises: a shaft having an upper end locked by the face plate and a lower end penetrating the base plate; and a biasing unit that is positioned on the base plate and biases the lower end of the shaft downward.

According to the first and fifth aspects of the invention, the face plate is supported by the columns at plural points in the placement region of the wafer while being pulled toward the base plate by the biasing unit of each of the tension members. Accordingly, even when the face plate (the substrate) is thinned, the face plate is not flexed downward by a weight thereof and is not bent upward by thermal expansion, so that the wafer can be reliably placed at a proper position on the face plate. Moreover, since heat capacity is reducible by thinning the face plate, temperatures for heating and cooling can be rapidly changed.

According to the second aspect of the invention, since the columns and the tension members are provided adjacent to each other, the face plate can reliably be pressed on the column members, so that flatness of the face plate can be maintained at a high accuracy.

According to the third aspect of the invention, load of the wafer is applied to the face plate through the wafer supporting unit. However, by securely supporting proximity of the wafer supporting unit by the columns, the face plate can be more reliably kept from being flexed. Moreover, by securely pulling the wafer supporting unit, the face plate can be more reliably bent. Accordingly, the placement position of the wafer is favorably maintained.

According to the fourth aspect of the invention, by interposing the compression spring (the biasing unit) between the nut and the base plate, the face plate can reliably be pulled toward the base plate through the nut and the shaft. In this arrangement, since the compression spring is located under the base plate, a space between the base plate and the face plate can effectively be used, so that a space for locating other components can easily be secured. Moreover, heat from the heating unit is shielded by the base plate to be unlikely to reach the compression spring, thereby hampering thermal deterioration of the compression spring.

### BRIEF DESCRIPTION OF DRAWINGS

FIG. 1 is an exploded perspective view of a schematic arrangement of a heating device according to an exemplary embodiment of the invention.

FIG. 2A is a cross-sectional view showing a face plate of the heating device.

FIG. 2B is another cross-sectional view showing the face plate of the heating device.

FIG. 3 is a cross-sectional view showing an arrangement for supporting the face plate on an outer circumference of a base plate.

FIG. 4 is a cross-sectional view showing an arrangement for supporting a wafer placement region of the face plate on the base plate.

FIG. 5 is a cross-sectional view showing an arrangement for holding a gap ball.

FIG. 6 is a cross-sectional view showing a ground arrangement by a ground member.

FIG. 7 is a perspective view showing the ground member.

FIG. 8 is an exploded perspective view showing a terminal block and a terminal.

FIG. 9A illustrates the modification of the invention.

FIG. 9B illustrates the modification of the invention.

FIG. 10A illustrates the another modification of the invention.

FIG. 10B illustrates the another modification of the invention.

### DESCRIPTION OF EMBODIMENT(S)

### Description of Whole Device

An exemplary embodiment of the invention will be described below with reference to the attached drawings.

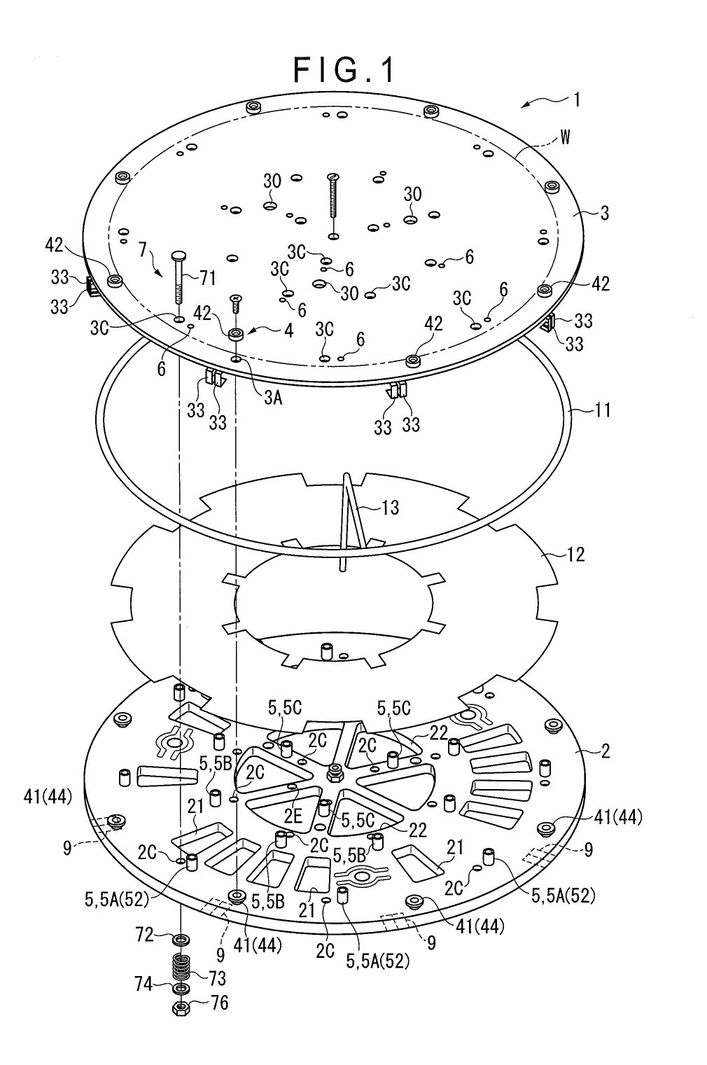

In FIG. 1, a heating device 1 is mounted in a coater developer device used in a semiconductor manufacturing process and is configured to heat a semiconductor wafer (hereinafter, simply referred to as a wafer) W such as a silicon wafer shown in a two-dot chain line to a predetermined temperature depending on various steps such as a pattern printing step.

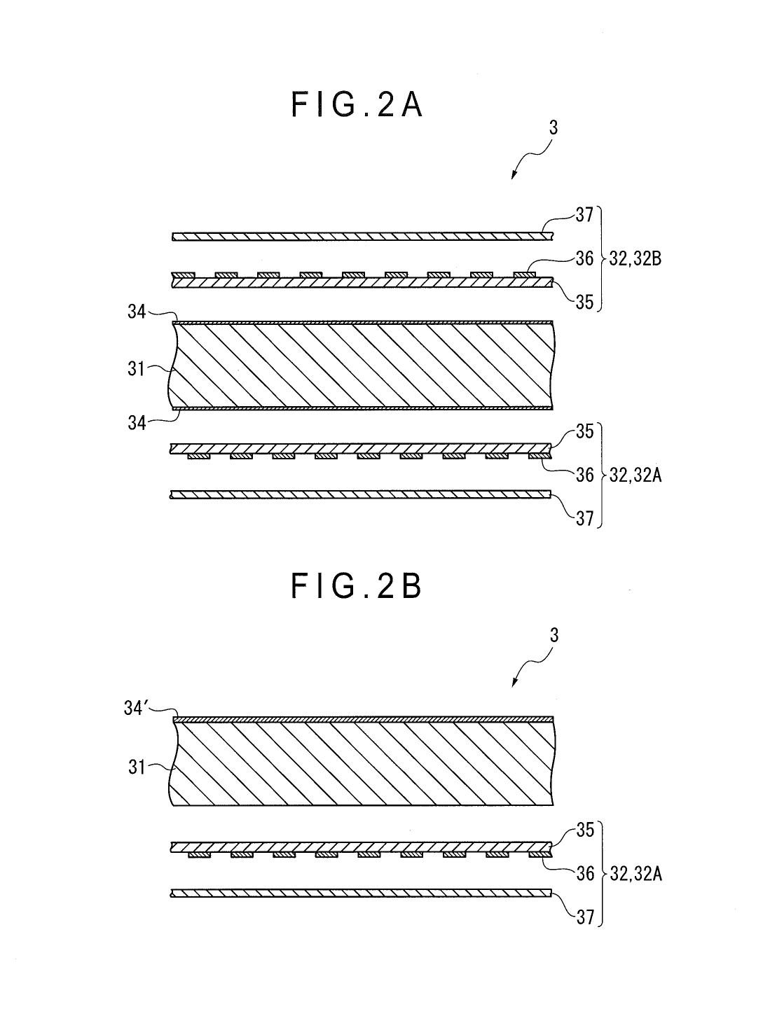

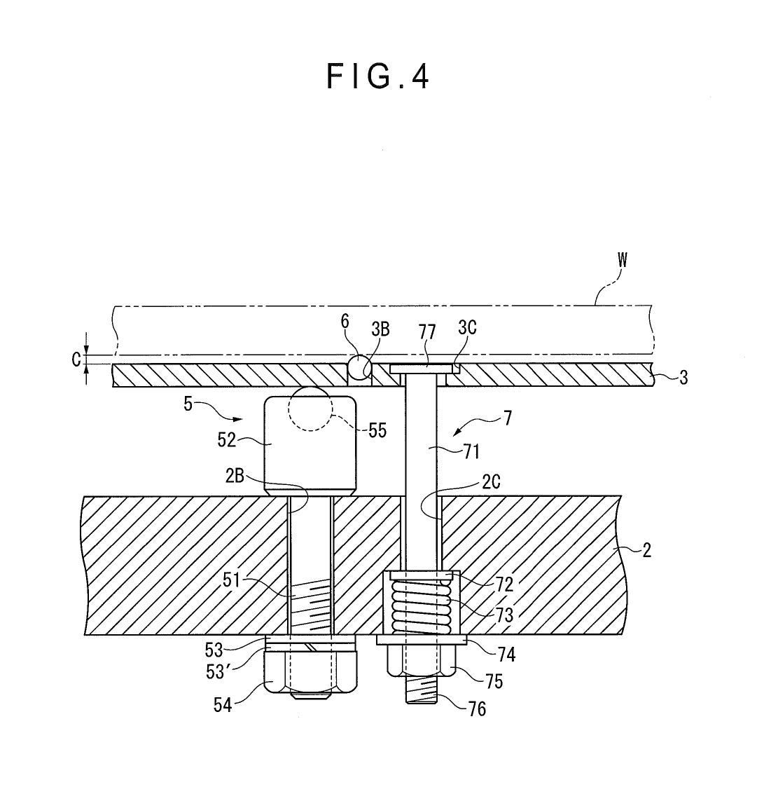

Specifically, the heating device 1 includes: a disc-shaped base plate 2; a disc-shaped face place 3 that is supported above the base plate 2; a cooling pipe 11 and a heat-shield rectifying plate 12 which are interposed between the base plate 2 and the face place 3, in which the wafer W placed on an upper surface of the face place 3 with a predetermined clearance C (FIG. 4) is heated by a later-described film heater 32 of the face place 3 (FIGS. 2A and 2B).

The face plate 3 has three through holes 30 each for an elevating pin (not shown) that moves the wafer W up and down. While the elevating pin is protruded through the through hole 30, the wafer W is delivered to the heating device 1 kept at a predetermined temperature by a hand robot and is mounted on an upper end of the elevating pin. Further, after the hand robot is moved away, the elevating pin is lowered, whereby the wafer W lowered with the elevating pin is placed on the face plate 3 via a gap ball(s) 6.

While the wafer W is processed, the wafer W is heated by the heating device 1 to be kept at a predetermined temperature. After a predetermined treatment is applied on the wafer W, the elevating pin is again raised. The wafer W raised with the elevating pin is delivered out of the heating device 1 by the hand robot and is replaced by another wafer W.

When processing conditions (recipe) for the wafer W are changed, for instance, the temperature of the face plate 3 is changed from a high temperature to a low temperature, refrigerant gas is fed in the cooling pipe 11, whereby the face plate 3 is cooled by the refrigerant gas ejected from ejection pores (not shown) of the cooling pipe 11. Subsequently, the refrigerant gas is guided to the heat-shield rectifying plate 12 and discharged from the center of the base plate 2. When the temperature of the face plate 3 falls to the predetermined temperature or less, supply of the refrigerant gas is stopped and the face plate 3 is again heated to be kept at the predetermined temperature depending on the processing conditions.

### Description of Base Plate

The base plate 2 is made of metal. In the exemplary embodiment, stainless steel is used for the base plate 2. The base plate 2 includes: a plurality of openings 21 for reducing a weight; and a discharge opening 22 that discharges refrigerant gas used for cooling the face plate 3 through the center of the base plate 2. Rigidity of the whole heating device 1 is secured by the base plate 2 having a sufficient thickness. Moreover, eight terminal blocks 9 are circumferentially provided at a circumferential equidistance on a lower surface near an outer circumference of the base plate 2 and are supplied with electricity from the outside (four of the terminal blocks 9 are shown in a broken line in FIG. 1).

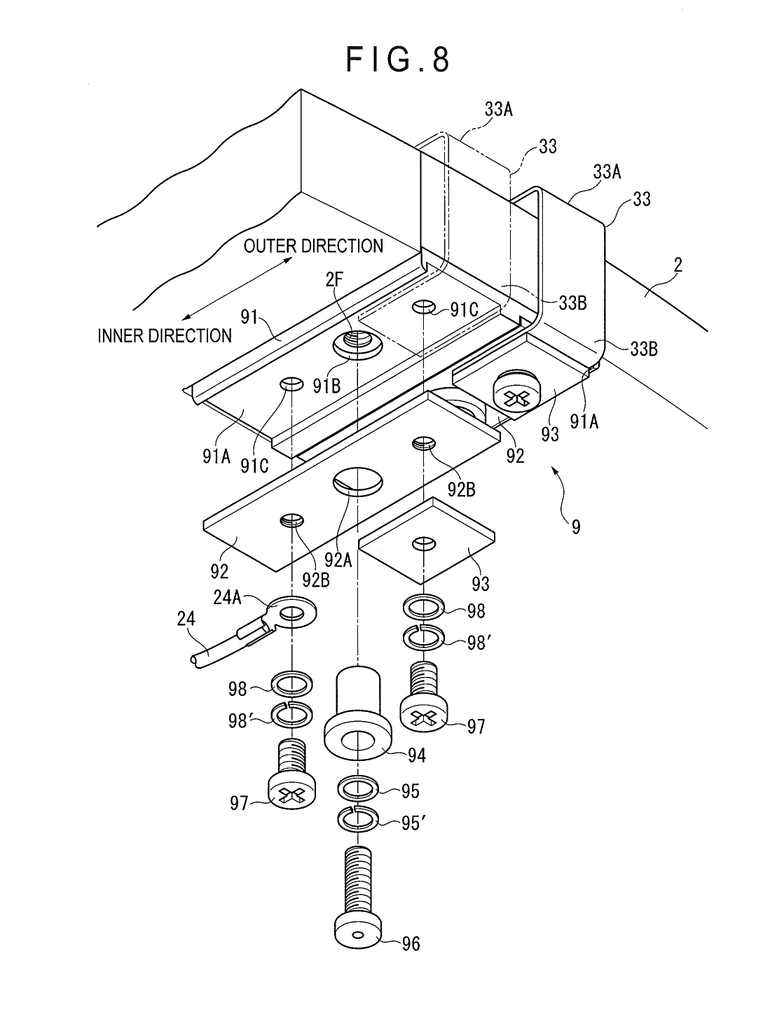

Each of the terminal blocks 9 is wired and connected with a terminal 33 that is extended from the film heater 32 and shaped in a channel (in a C-shape) and a wire 24 (FIG. 8) from an external power source (not shown). Electricity is supplied to the film heater 32 by establishing an electric continuity between the terminal 33 and the wire 24 via the terminal block 9. A specific arrangement of the terminal block 9 and the terminal 33 will be described later.

### Description of Face Plate

As shown in FIG. 2A, the face plate 3 has an arrangement in which the film heater 32 (32A, 32B) is attached by a hot pressing to both of upper and lower surfaces of an aluminum substrate 31. As shown in FIG. 1, the face plate 3 is supported by the base plate 2 via eight wafer guides 4 that are disposed at a circumferential equidistance on the outermost circumference of the face plate 3 and a plurality of columns 5 disposed in appropriate positions inside the wafer guides 4. A specific supporting arrangement of the wafer guides 4 and the columns 5 will also be described later.

The aluminum substrate 31 is a thin plate. In the exemplary embodiment, the aluminum substrate 31 has a 1.5-mm thickness. The whole aluminum substrate 31 is treated with an anodized-aluminum processing to form an anodized-aluminum layer 34. Such an anodized-aluminum processing is applied on an outer circumferential end of the aluminum substrate 31 and an inside of each of various through holes, in addition to the both of the upper and lower surface of the aluminum substrate 31.

The film heater 32 includes: a base film 35; a stainless steel foil 36 that forms a circuit pattern for heat generation on a surface of the base film 35; and a cover film 37 that covers the circuit pattern. The films 35 and 37 are made of a polyimide resin. The terminal 33 (FIG. 1) is provided to a film heater 32A adhered on the lower surface of the aluminum substrate 31 to face the base plate 2 for supplying electricity to the film heater 32A. However, since no terminal is provided to a film heater 32B adhered on the upper surface of the aluminum substrate 31 to face the wafer W, no electricity is supplied.

In other words, the film heater 32B on the upper surface is a dummy member having substantially the same circuit pattern as the film heater 32A. Linear expansion coefficients on both the upper and lower surfaces of the aluminum substrate 31 can be equalized by adhering the film heaters 32A and 32B both of which have substantially the same arrangement respectively on the upper and lower surfaces of the aluminum substrate 31, thereby suppressing flexure caused by thermal expansion during a heating process. As a result, the face plate 3 is expanded mainly in an in-plane direction (the same direction as a radial direction) from the center toward the outside. As long as there is no difference in the linear expansion coefficient of the circuit pattern between the film heaters 32A and 32B, any circuit pattern is applicable. The circuit pattern is not limited to substantially the same one as that of the film heater 32A.

Further, as shown in FIG. 2B, an anodized-aluminum layer 34′ having a thickness enough to eliminate the difference in the linear expansion coefficient may be formed on the upper surface of the aluminum substrate 31 in place of the dummy film heater 32B. In this arrangement, it is not necessary to provide an anodized-aluminum layer on the lower surface of the aluminum substrate 31.

The heat-generating surface of the film heater 32 is provided by a circle at the center and a circular ring outside of the circle, the circle and the circular ring being appropriately divided into small regions. The circuit pattern (not shown) of the film heater 32 (heating unit) is formed such that electricity is independently supplied to each of the small regions. Since the heat-generating surface is divided into a plurality of small regions and the plurality of small regions each independently generate heat, a temperature distribution of the heated wafer W can be further equalized to reduce heating unevenness.

In the exemplary embodiment in which a plurality of circuit patterns are formed corresponding to the small regions, eight terminal blocks 9 are provided and eight pairs of the terminals 33 (i.e., 16 terminals) for supplying electricity are provided. Among the 16 terminals, a terminal 33 that does not supply electricity to the plurality regions is designed as a dummy, which is not electrically connected with the circuit pattern for heat generation.

It is desirable that the heat-generating surface of the film heater 32 is divided into the plurality of small regions in order to heat the wafer W evenly. Essentially, when the number of the terminal 33 is the same as that of the regions, electricity is sufficiently supplied to the regions. However, in consideration of influence of a reaction force (elastic force) of the terminal 33 on a stress to the thin aluminum substrate 31, the pairs of terminals 33 are preferably disposed at a circumferential equidistance in a circumferential direction. However, since it is not general because of a manufacturing reason to dispose the number of the terminals 33 corresponding to the regions to be supplied with electricity at a circumferential equidistance, eight pairs of the terminals 33 (including the dummy) are provided at a circumferential equidistance.

In the above face plate 3, electricity is supplied to the stainless steel foil 36 of the film heater 32A on the lower side of the face plate 3, whereby the film heater 32A generates heat to heat the aluminum substrate 31. When the aluminum substrate 31 is heated, the wafer W placed on the face plate 3 through gas existing immediately above the whole face plate 3 is heated. Temperature control at this time is conducted by adjusting electricity supply to the film heater 32A based on a signal from a temperature sensor (not shown) embedded in the aluminum substrate 31.

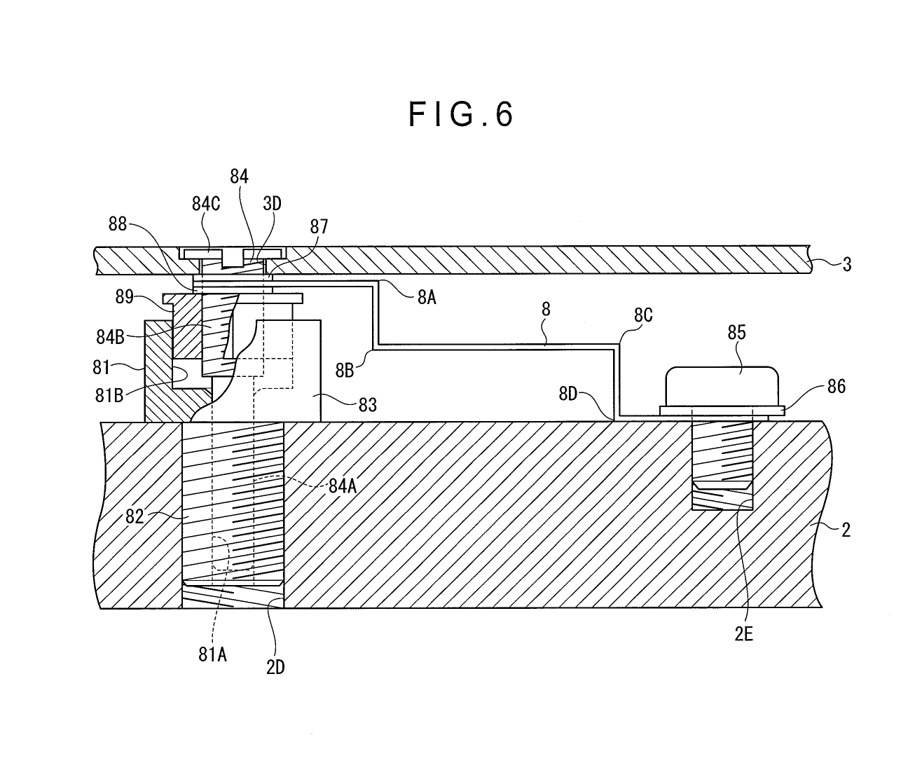

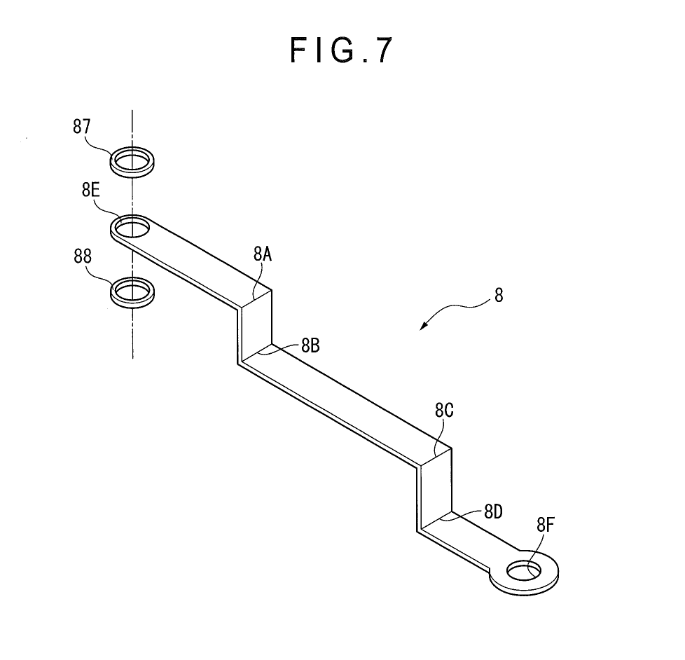

Since the face plate 3 is configured to sandwich the conductive aluminum substrate 31 with the insulative polyimide resin, the whole face plate 3 works as a capacitor to be electrified. Further, when a pin hole exists in the base film 35, there is a possibility that charges electrified on the aluminum substrate 31 are easily leaked. For this reason, in the exemplary embodiment, at the center of the lower surface of the face plate 3, a part of a base material surface of the aluminum substrate 31 is exposed and the exposed part is short-circuited to the base plate 2 through a ground member 8 (FIGS. 6 and 7) to be grounded. A ground arrangement by the ground member 8 will also be described in detail later.

### Description of Cooling Pipe

Additionally, the annular cooling pipe 11 and the annular heat-shield rectifying plate 12 are disposed between the base plate 2 and the face plate 3. A supply pipe 13 is connected to the cooling pipe 11 through the central discharge opening 22, whereby the refrigerant gas is supplied into the cooling pipe 11 through the supply pipe 13. The refrigerant gas is ejected toward the center from a plurality of ejection pores (not shown) provided to the cooling pipe 11 to cool the face plate 3 from beneath.

Since the heat capacity of the face plate 3 is kept small by using the thin aluminum substrate 31 having a small thickness, a rapid temperature-change from heating to cooling can be achieved by switching ON or OFF for supplying electricity to the film heater 32A. Further, by effectively cooling the face plate 3 by the refrigerant gas ejected from the cooling pipe 11, more rapid temperature-change can be achieved.

### Description of Heat-Shield Rectifying Plate

The heat-shield rectifying plate 12 prevents the refrigerant gas ejected through the cooling pipe 11 from being discharged from the opening 21 provided to the base plate 2, guides the refrigerant gas to the discharge opening 22 at the center to promote discharge of the refrigerant gas, and shields the base plate 2 from radiation heat of the heat-generating face plate 3. With this arrangement, thermal expansion of the base plate 2 and thermal influence on various components attached to the base plate 2 can be inhibited.

### Description of Support Arrangement for Face Plate by Wafer Guide

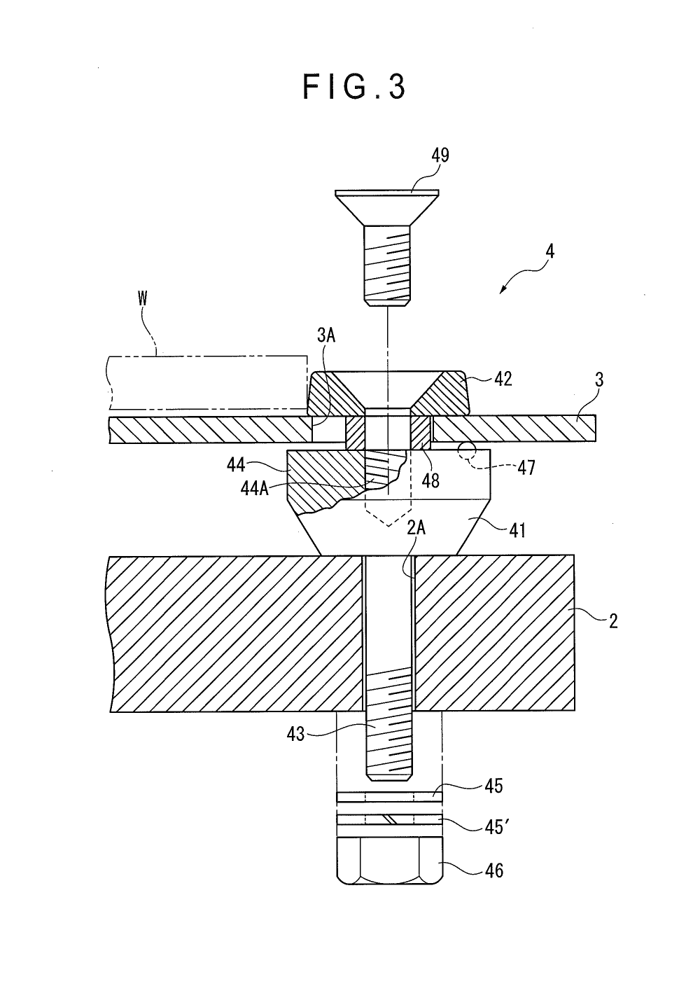

A support arrangement for the face plate 3 by a wafer guide 4 on an outer circumference of the face plate 3 will be described below with reference to FIGS. 1 and 3.

Firstly, a first through hole 2A vertically penetrating the base plate 2 treated with the anodized-aluminum processing is provided at eight points on the outer circumference of the base plate 2. On the other hand, the wafer guide 4 includes: a support bolt 41 that is inserted into the first through hole 2A from above; and a resin-made guide member 42 that is provided on the upper surface of the face plate 3 and with which a periphery of the wafer W is brought into contact.

The support bolt 41 has a male screw 43 that penetrates the first through hole 2A of the base plate 2 and a mount portion 44 that is integrally formed on the male screw 43 and on which the face plate 3 is placed. The support bolt 41 is fixed to the base plate 2 by putting a flat washer 45 and a spring washer 45′ on the male screw 43 that projects from a lower surface of the first through hole 2 and by screwing a nut 46 onto the male screw 43 while the mount portion 44 is placed on the upper surface of the base plate 2.

An upper surface of the mount portion 44 of the support bolt 41 is made flat. A ceramic first support ball 47 having an extremely small diameter is press-fitted into a part of the upper surface of the mount portion 44. A part of the first support ball 47 projects beyond the upper surface of the mount portion 44 by a predetermined dimension. In other words, the face plate 3 to be placed on the mount portion 44 is specifically placed in point contact with the first support ball 47. Since a contact area with the face plate 3 is reduced by such a point contact, thermal transmission from the face plate 3 can be inhibited and thermal expansion and shrinkage of the face plate 3 in a radial direction is not hampered. Since the first support ball 47 is made of ceramics, a thermal conductivity of the first support ball 47 is lower than that of aluminum used for the face plate 3. Thus, thermal transmission from the face plate 3 can also be inhibited. Further, the ceramic first support ball 47 is suitable for clean environments.

While the face plate 3 is placed on the mount portion 44, a metallic ring member 48 is inserted in an anodized-aluminum treated first attachment hole 3A on the face plate 3 and is placed on the upper surface of the mount portion 44. A dish screw 49 penetrates the ring member 48 and is screwed into a female screw 44A of the mount portion 44, whereby the guide member 42 is fixed to the mount portion 44.

In such an arrangement, the face plate 3 is held to be fixed between a lower surface of the guide member 42 and the first support ball 47. While the face place 3 is held by fastening the dish screw 49, the lower surface of the guide member 42 is brought into contact with the ring member 48, so that the dish screw 49 can be kept from being excessively fastened. When the dish screw 49 is excessively fastened into the face plate 3, a corresponding part of the face plate 3 is deformed into a wavy shape, so that the wafer W cannot be placed at a proper position. The first attachment hole 3A of the face plate 3 is formed to be an elongated hole having a predetermined length along the radial direction of the face plate 3 and allows thermal expansion and shrinkage of the face plate 3 in the radial direction. The guide member 42 may be fixed to the face plate 3 by not only screwing but also any fixing unit while being biased toward the base plate 2.

### Description of Support Arrangement for Face Plate by Column

A support arrangement for the face plate 3 by the column 5 will be described below with reference to FIGS. 1 and 4.

The face plate 3 is supported by the base plate 2 through the plurality of columns 5. The columns 5 are provided by: eight columns 5A disposed at a circumferential equidistance outside the wafer W shown in a two-dot chain line; eight columns 5B disposed at a circumferential equidistance in a placement region of the wafer W (i.e., at an inner position relative to the columns 5A); and three columns 5C disposed at a circumferential equidistance at an inner position relative to the columns 5B.

A second through hole 2B vertically penetrating the base plate 2 is provided at a position corresponding to each of the columns 5 of the base plate 2. The column 5 is provided by a bolt to be inserted into the second through hole 2B from above. The column 5 has a male screw 51 that penetrates the second through hole 2B and a mount portion 52 that is integrally formed on the male screw 51 and on which the face plate 3 is placed. The column 5 is fixed to the base plate 2 by putting a flat washer 53 and a spring washer 53′ on the male screw 51 that projects from the lower surface of the second through hole 2B and screwing a nut 54 on the male screw 51 while the mount portion 52 is placed on the upper surface of the base plate 2.

An upper surface of the mount portion 52 is also made flat. A ceramic second support ball 55 larger than the first support ball 47 is press-fitted into the center of the upper surface. A part of the second support ball 55 projects beyond the upper surface of the mount portion 52 by a predetermined dimension. In other words, the face plate 3 to be placed on the mount portion 44 is placed in point contact with the second support ball 55 in the same manner as in the support arrangement by the wafer guide 4. Advantages by such a point contact are the same as those of the support arrangement by the wafer guide 4.

Since the face plate 3 is supported not only by the wafer guide 4 on the outer circumference but also by the columns 5B and 5C from beneath at the plural positions within the placement region of the wafer W, the face plate 3 can be prevented from being flexed (projected) downward due to a self-weight although being made of the thin aluminum substrate 31 having a small rigidity, so that the wafer W can be reliably placed at a proper position.

A second attachment hole 3B that penetrates the aluminum substrate 31 and the film heaters 32A and 32B respectively provided on upper and lower surfaces of the aluminum substrate 31 is provided near the position of the column 5 to support the face plate 3. In the exemplary embodiment, the second attachment hole 3B penetrates the film heater 32A on the lower surface, but does not necessarily penetrate the film heater 32A. A ceramic gap ball 6 (a wafer supporting unit) is press-fitted into the second attachment hole 3B from above and is held therein.

The gap ball 6 projects beyond the upper surface of the face plate 3 by a predetermined amount. This projection amount corresponds to the clearance C in FIG. 4. Specifically, the wafer W is supported on the gap ball 6 in point contact with each other and placed at a proper position such that the clearance C of a predetermined dimension from the upper surface of the face plate 3 is uniformly kept. It should be noted that the gap ball 6, a diameter of the second attachment hole 3B and a size of the clearance C are shown in an exaggeratedly larger size relative to the thickness of the face plate 3 in consideration of viewability.

The gap ball 6 is not necessarily provided near all the support positions by the columns 5. At the support positions by the columns 5B, the gap ball 6 is provided near four (every other column) of the eight columns 5B. However, the gap ball 6 may be provided at positions corresponding to all the columns 5 The location of the gap ball 6 may be determined as needed in implementation.

### Description of Tension Member

A tension member 7 that biases the face plate 3 downward is provided near the support positions by the columns 5 The tension member 7 is not necessarily provided near all the support positions by the columns 5 However, the column 5 is requisite at a position where the gap ball 6 and the tension member 7 are used in combination. The column 5 may be used alone, or may be used at a position where one of the gap ball 6 and the tension member 7 is present near the column 5.

As shown in FIG. 4, the base plate 2 is provided with a third through hole 2C. The face plate 3 is provided with a third attachment hole 3C at a position corresponding to the third through hole 2C. The third through hole 2C has a stepped shape having a countersunk hole from the underneath. The third attachment hole 3C has a stepped shape having a countersunk hole from above.

The tension member 7 includes: a shaft 71 that is inserted into both of the third through hole 2C of the base plate 2 and the third attachment hole 3C of the face plate 3; a washer 72 that is inserted onto the shaft 71 projecting downward from the third through hole 2C and is placed in the third through hole 2C; a coil spring 73 that is also inserted onto the shaft 71 and is placed under the washer 72; a washer 74 that is inserted onto the shaft 71 and is brought into contact with the lower surface of the base plate 2; and a nut 75 that is screwed onto the male screw 76 on the lower side of the shaft 71.

The washer 72 is pushed upward to the stepped part in the third through hole 2C via the washer 74 and the coil spring 73 by fastening the nut 75 to be brought into contact with the stepped part. Since the coil spring 73 is a compression spring and is provided in the base plate 2 and between the base plate 2 and the nut 75, the coil spring 73 is compressed by further fastening the nut 75. After the nut 75 is screwed until the washer 74 is brought into contact with the lower surface of the base plate 2, by further fastening the nut 75, the washer 74 and the nut 75 on the lower side of the shaft 71 is biased downward by a reaction force of the compressed coil spring 73, whereby the whole shaft 71 is biased downward.

In the third attachment hole 3C of the face plate 3, a head 77 that is shaped in a flange and provided at an upper end of the shaft 71 is locked by the stepped portion, whereby the face plate 3 is biased downward through the head 77. In other words, the tension member 7 pulls the face plate 3 downward from the base plate 2, whereby no projecting part beyond the upper surface of the face plate 3 exists. Accordingly, the tension member 7 does not interfere with the wafer W although the placement region of the wafer W on the face plate 3 is biased downward.

With the above arrangement, the lower surface of the face plate 3 is supported in point contact with the second support ball 55 on the column 5 while the face plate 3 is pulled downward by the tension member 7. As a result, flatness of the face plate 3 can be maintained at a high accuracy and the wafer W can be reliably placed at a proper position. Moreover, since the tension member 7 does not project beyond the upper surface of the face plate 3 and the aluminum substrate 31 forming the face plate 3 is thinned, the thickness of the whole heating device 1 can also be reduced.

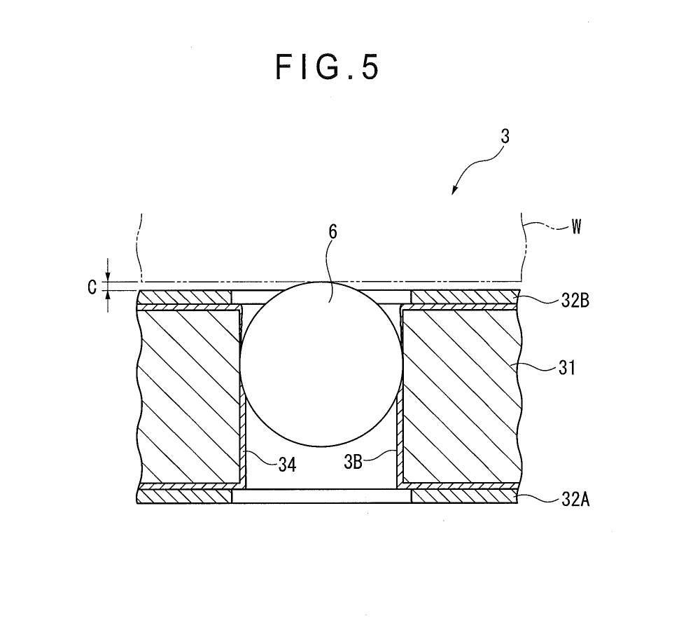

Description of Arrangement for Holding Gap Ball With reference to FIG. 5, an arrangement for holding the gap ball 6 will be described.

The gap ball 6 is press-fitted into an inner wall of the second attachment hole 3B penetrating the face plate 3 and held by the inner wall. Specifically, the gap ball 6 is held only by the inner wall of the second attachment hole 3B in the aluminum substrate 31, and a holding position in the second attachment hole 3B is located on the upper side from the center of the aluminum substrate 31 in the thickness direction. In the exemplary embodiment, the gap ball 6, which has a diameter larger than the thickness of the aluminum substrate 31, is press-fitted to a position slightly higher than the center of the aluminum substrate 31 in the thickness direction, thereby ensuring a predetermined projection amount of the gap ball 6.

When the gap ball 6 is press-fitted into the second attachment hole 3B from above, a surface of the anodized-aluminum layer 34 provided on the inner wall of the aluminum substrate 31 is thinly scraped, but still remains When the gap ball 6 is deeply press-fitted into the second attachment hole 3B to a position lower than the center of the aluminum substrate 31 in the thickness direction, the anodized-aluminum layer 34 at an entire part below the press-fitted position is possibly peeled off from the inner wall by external force from above to drop off In such a case, since a holding force of the gap ball 6 by the part below the gap ball 6 is reduced, the gap ball 6 cannot be stably held, so that the clearance C cannot be kept. In contrast, in the exemplary embodiment, since the gap ball 6 is held at the upper position from the center of the aluminum substrate 31 in the thickness direction, the anodized-aluminum layer 34 does not drop off to keep the clearance C more reliably.

Moreover, according to the exemplary embodiment, since the second attachment hole 3B is provided in a manner to penetrate the aluminum substrate 31, the second attachment hole 3B has no bottom to be formed as a part of the aluminum substrate 31, whereby the gap ball 6 is not placed on such a bottom. Accordingly, the gap ball 6 can be free from thermal influence caused by deformation of such a thin bottom. Even if the second attachment hole 3B does not penetrate the aluminum substrate 31 and the aluminum substrate 31 has a bottom, it is only necessary that the gap ball 6 is not in contact with the bottom. Even in such an arrangement, influence on the gap ball 6 by thermal expansion and shrinkage at the bottom can be reduced.

Additionally, since no sealed space is formed under the gap ball 6 because the second attachment hole 3B has no bottom formed by the aluminum substrate 31, such inflation of air in a sealed space by being heated to push up the gap ball 6 does not occur, so that the clearance C is also favorably kept.

### Description of Ground Arrangement by Ground Member

With reference to FIGS. 1, 6 and 7, a ground arrangement by the ground member 8 will be described.

As shown in FIGS. 1 and 6, a fourth through hole 2D penetrating the base plate 2 is provided at the center of the base plate 2. An inside of the fourth through hole 2D is tapped. Moreover, a screw hole 2E is provided at a position away from the fourth attachment hole 2D of the base plate 2 by a predetermined dimension.

On the other hand, a fourth attachment hole 3D penetrating the face plate 3 is provided at a position corresponding to the fourth through hole 2D of the face plate 3.

A holding bolt 81 is screwed into the fourth through hole 2D of the base plate 2 from above. The holding bolt 81 has a male screw 82 to be screwed into the fourth through hole 2D and a cylindrical head 83 integrated on an upper end of the male screw 82. A guide hole 81A is provided at the center of an inside of the holding bolt 81 in a manner to penetrate the holding bolt 81 in an axial direction. A part of the holding bolt 81 corresponding to the head 83 of the guide hole 81A is radially wider than a part of the holding bolt 81 corresponding to the male screw 82 and is defined as a hexagonal holder 81B in a plan view.

A hexagonal nut 89 is slidably fitted in the holder 81B. An elongated screw 84 that is inserted in the fourth attachment hole 3D of the face plate 2 from above is screwed into the nut 89. The elongated screw 84 includes: a rod 84A that is provided on a lower end and inserted into the guide hole 81A of the holding bolt 81; a male screw 84B that is integrally formed on an upper end of the rod 84A and screwed into the nut 89; and a head 84C that is integrally formed on an upper end of the male screw 84B and locked by a countersunk hole in the fourth attachment hole 3D of the face plate 3. The elongated screw 84 penetrates a first end (upper end) of the ground member 8 that is interposed between the lower surface of the face plate 3 and the nut 89.

As shown in FIGS. 6 and 7, the ground member 8 is a belt made of a conductive metal such as stainless steel and bent alternately in peaks and troughs to form a stepped structure with first to fourth bent portions 8A, 8B, 8C and 8D. A through hole 8E in which the elongated screw 84 is inserted is provided at the first end of the ground member 8 while a through hole 8F in which a screw 85 is inserted is provided at a second end (a lower end) of the ground member 8. The screw 85 is screwed into the screw hole 2E while the second end of the ground member 8 is held between the upper surface of the base plate 2 and the washer 86.

At the first end of the ground member 8, a washer 87 made of a conductive metal is disposed between the lower surface of the face plate 3 and the ground member 8 and the elongated screw 84 is inserted into the washer 87. A part of the film heater 32A (FIGS. 2A and 2B) facing the washer 87 is provided with an opening slightly larger than a diameter of the washer 87. A part of the aluminum substrate 31 (FIGS. 2A and 2B), which is slightly larger than the diameter of the washer 87, is not treated with the anodized-aluminum processing. A thickness of the washer 87 is more than a thickness of an insulative layer formed by the anodized-aluminum layer 34 and the film heater 32A. As a result, when the elongated screw 84 is fastened by a predetermined fastening force, the washer 87 is brought into contact with a base material portion of the aluminum substrate 41 to establish electric continuity. Accordingly, electric continuity between the ground member 8 and the aluminum substrate 31 through the washer 87 is established, so that the aluminum substrate 31 is grounded to the base plate 2 through the ground member 8.

Herein, a resin washer 88 having heat shielding property and insulation property is disposed between the ground member 8 and the nut 89 and the elongated screw 84 is inserted in the resin washer 88. Accordingly, heat through the face plate 3 cannot be easily transmitted to the nut 89 and the holding bolt 81, thereby inhibiting thermal transmission. Moreover, since the ground member 8 is provided at the center of the face plate 3, even if heat is transmitted from the aluminum substrate 31 of the face plate 3 to the base plate 2, thermal influence on the aluminum substrate 31 becomes even, so that the face plate 3 is less likely to be influenced than when the ground member is provided at an end of the face plate 3.

Since the ground member 8 is provided with the first to fourth bent portions 8A to 8D in a longitudinal direction, the external force applied on the ground member 8 is absorbed in bents at the first to fourth bent portions 8A to 8D, so that a reaction force against the external force is unlikely to occur at both ends of the ground member 8. Accordingly, the lower surface of the face plate 3 is not pushed upward particularly through the first end of the ground member 8, thereby preventing the center of the face plate 3 from being deformed by being pushed upward.

Moreover, with this ground member 8, displacement of the ground member 8 in the longitudinal direction due to thermal expansion and shrinkage can be received by the bents at the first to fourth bent portions 8A to 8D.

In the aforementioned arrangement, in a step before supporting the face plate 3 with the base plate 2, the second end of the ground member 8 is fixed to the base plate 2 with the screw 85. Moreover, the nut 89 and the like are housed in the holder 81B of the holding bolt 81 that is screwed in the base plate 2. The first end of the ground member 8 as well as the washers 87 and 88 are positioned on the nut 89.

In a step to arrange the base plate 2 to support the face plate 3, the elongated screw 84 is inserted into the fourth attachment hole 3D of the face plate 3 and simultaneously inserted into the ground member 8, the washers 87 and 88, the nut 89 and the holding bolt 81. Subsequently, when the rod 84A of the elongated screw 84 is rotated while being guided by the guide hole 81A of the holding bolt 81, the nut 89 slides upward within the holder 81 without rotation while being screwed onto the elongated screw 84. Eventually, the ground member 8 and the washers 87 and 88 are held between the lower surface of the face plate 3 and the nut 89.

### Description of Terminal Block and Terminal

As shown in FIG. 8, the terminal block 9 includes: a resin-made insulative platform 91 that is fixed to the lower surface of the base plate 2; a pair of metallic conductive plates 92 that are attached to the platform 91; and a press member 93 that is attached to an outer end of the conductive plates 92.

An outer end edge of the platform 91 is substantially flush with an end surface of the base plate 2. The platform 91 has two lines of attachment grooves 91A in inner and outer directions (the same direction as the radial direction of the base plate 2). The conductive plates 92 are disposed in the attachment grooves 91A. Through holes 91B and 92A respectively penetrating the attachment groove 91A and the conductive plate 92 are provided at the center in the longitudinal direction of the attachment groove 91A and the conductive plate 92. A resin-made insulative cylindrical member 94 is inserted into the through holes 91B and 92A.

A screw 96 after being inserted through a flat washer 95 and a spring washer 95′ is inserted into the cylindrical member 94. The screw 96 is screwed into a screw hole 2F provided on the base plate 2. With this screw 96, the platform 91 is fixed to the base plate 2 and the conductive plate 92 is fixed to the platform 91. Herein, the screw 96 to be screwed in the base plate 2 is insulated from the conductive plate 92 because the screw 96 is inserted in the cylindrical member 94. Accordingly, the conductive plate 92 is not electrically connected with the base plate 2.

In the conductive plate 92, screw holes 92B are provided on both sides of the through hole 92A. A screw 97 is screwed into each of the screw holes 92B. In the platform 92, a circular hole 91C is provided at a position corresponding to each of the screw holes 92B. The circular hole 91C serves for avoiding interference between a tip end of the screw 97 projecting through the screw hole 92B and the platform 91.

The screw 97 screwed to the conductive plate 92 on an inner side is inserted into a solderless terminal 24A of a wire 24 through a flat washer 98 and a spring washer 98′. The wire 24 is wired and connected to the conductive plate 92 by screwing the screw 97 into the screw hole 92B.

The screw 97 screwed to the conductive plate 92 on an outer side is inserted into the press member 93 through the flat washer 98 and the spring washer 98′ and inserted into a terminal 33 of the film heater 32A (FIGS. 2A and 2B). When the screw 97 is screwed into the screw hole 92B, the terminal 33 is wired and connected to conductive plate 92 in a manner to be pressed down by the press member 93.

FIG. 8 illustrates the base plate 2 and the terminal block 9 from the underneath. However, an attachment operation of the base plate 2 to the terminal block 9 and wire connection of the wire 24 and the terminal 33 are performed with the lower surface of the base plate 2 facing upward.

The terminal 33 wired and connected to the terminal block 9 is shaped in a channel (in a C-shape) having first and second bent portions 33A and 33B. Since the terminal 33 has the first and second bent portions 33A and 33B, in the same manner as in the ground member 8 as described above, the external force applied on the terminal 33 is absorbed in the bents at the first and second bent portions 33A and 33B, so that a reaction force against the external force is unlikely to occur at both ends of the terminal 33. Accordingly, the lower surface of the face plate 3 is neither pushed upward nor pulled downward particularly through a base end of the terminal 33, thereby preventing such deformation of the face plate 3 as an outer circumference of the face plate 3 is pushed upward or pulled downward. Even when the face plate 3 is pushed upward or pulled downward for some reason, since the terminal 33 is provided at a circumferential equidistance, the face plate 3 is not deformed into an irregular shape to reduce influence by the deformation.

Since the terminal block 9 is attached to the lower surface of the base plate 2, by facing the lower surface of the base plate 2 upward, the wire connection and the like of the terminal 33 can be easily performed to enhance operability.

The terminal block 9 is typically attached to the upper surface of the base plate 2 and housed in a space between the base plate 2 and the face plate 3. However, by attaching the terminal block 9 to the lower surface of the base plate 2, a clearance between the base plate 2 and the face plate 3 can be entirely narrowed, so that the thickness of the whole heating device 1 can be reduced.

It should be noted that the scope of the invention is not limited to the above-described exemplary embodiment(s) but includes modifications and improvements as long as the modifications and improvements are compatible with the invention.

For instance, although the tension members 7 are provided near all the support positions by the columns 5, the tension members 7 are not necessarily provided near all the support positions. The invention encompasses an arrangement in which the tension members 7 are provided only near several support positions selected as needed and an arrangement in which the tension members 7 are provided at positions except for the proximity of the support positions by the columns 5. In short, it is only necessary that the part of the face plate 3 corresponding to the placement region of the wafer W is biased downward by the tension members 7 from the base plate 2.

In the above exemplary embodiment, the film heater 32A is used as the heating unit of the invention. However, as long as a circuit pattern for heat generation can be formed on the substrate, no film heater needs to be used.

In the above exemplary embodiment, the coil spring 73 is used as a biasing unit of the invention. However, a cylindrical rubber member and the like having elastic force may alternatively be used.

In the above exemplary embodiments, the gap ball 6 is used as the wafer supporting unit. However, the wafer supporting unit is not limited to the gap ball 6 but may be a protrusion shaped substantially in a cone narrowed toward a tip end.

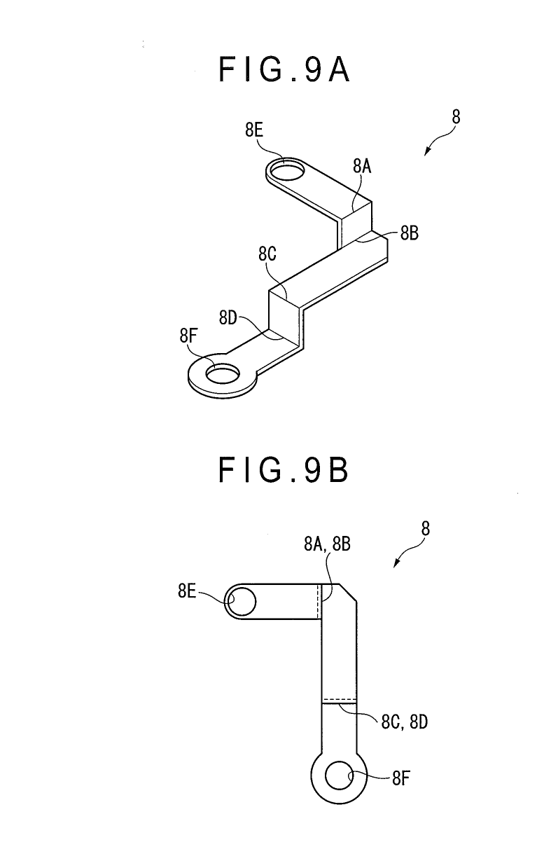

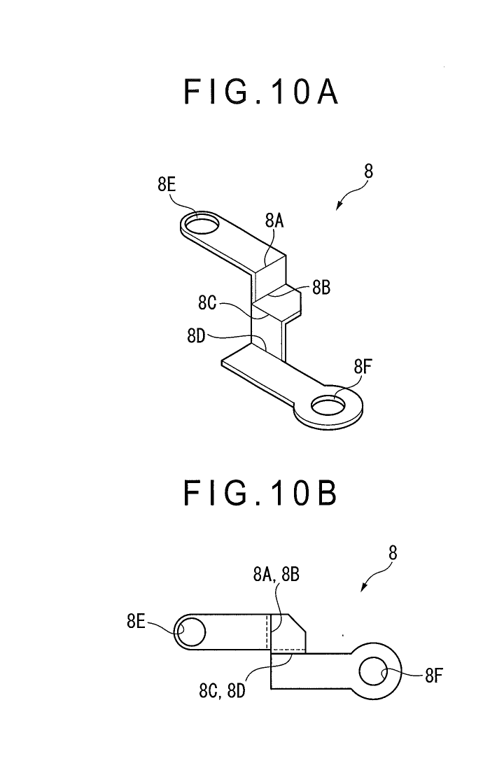

In the above exemplary embodiment, the shape of the ground member 8 is in a straight line extending from the center of the heating device 1 toward the radial outside in a plan view. However, the shape of the ground member 8 is not limited thereto. For instance, as shown in FIGS. 9A and 9B, the ground member 8 may be formed in an L-shape in a plan view by changing an extension direction of the ground member 8 by 90 degrees at the second bent portion 8B. Alternatively, as shown in FIGS. 10A and 10B, the ground member 8 may be formed in a crank shape in a plan view by changing the extension direction of the ground member 8 by 90 degrees at the second bent portion 8B and again changing the extension direction by 90 degrees at the fourth bent portion 8D to return to the initial extension direction.

In the thus shaped ground member 8, with the bents of the first and second bent portions 8A and 8B and the bents of the third and fourth bent portions 8C and 8D, the ground member 8 can receive displacement in two directions orthogonal to each other.

### INDUSTRIAL APPLICABILITY

The invention is applicable for heating a semiconductor wafer.

### EXPLANATION OF CODES

1: heating device, 2: base plate, 3: face plate, 5: column, 6: gap ball (wafer supporting unit), 7: tension member, 9: terminal block, 11: cooling pipe, 12: heat-shield rectifying plate, 24: wire, 32,32A: film heater (heating unit), 33: terminal, 71: shaft, 73: coil spring as a compression spring (biasing unit), 75: nut, W: wafer.

1. A heating device comprising:
a base plate;
a face plate that is positioned above the base plate, on which a wafer is placed and to which a heating unit for heating the wafer is provided;
a plurality of columns that are vertically provided between the base plate and the face plate and supports the face plate; and
a plurality of tension members that pull the face plate toward the base plate, wherein
the columns and the tension members are positioned to support and pull at least a portion of the face plate corresponding to a placement region of the wafer, and
each of the tension members comprises: a shaft having an upper end locked by the face plate and a lower end penetrating the base plate; and a biasing unit that is positioned near the base plate and biases the lower end of the shaft downward.

2. The heating device according to claim 1, wherein
the columns and the tension members are positioned adjacent to each other.

3. The heating device according to claim 2, wherein
the face plate is provided with a plurality of wafer supporting units that support the wafer with a predetermined clearance between the wafer and an upper surface of the face plate, and
the wafer supporting units are provided adjacent to both of the columns and the tension members.

4. The heating device according to claim 1, wherein
each of the tension members has a nut to be screwed onto a lower part of the shaft, and
the biasing unit of each of the tension members is provided by a compression spring that is inserted onto the shaft and is interposed between the base plate and the nut.

5. A heating device comprising:
a base plate;
a face plate that is positioned above the base plate and on which a wafer is placed;
a cooling pipe that is interposed between the base plate and the face plate and through which refrigerant gas for cooling the face plate circulates;
a heat-shield rectifying plate that is interposed between the base plate and the face plate to guide the refrigerant gas ejected through the cooling pipe and shields the base plate from radiation heat of the face plate;
a wafer supporting unit that is provided in a manner to project beyond an upper surface of the face plate;
a heating unit that is provided to the face plate and is adapted to heat the wafer;
a terminal block that is attached to the base plate and to which an electricity-supply terminal provided to the heating unit and a wire from an external power source are connected;
a plurality of columns that are vertically provided between the base plate and the face plate and supports the face plate; and
a plurality of tension members that pull the face plate toward the base plate, wherein
the columns and the tension members are positioned to support and pull at least a portion of the face plate corresponding to a placement region of the wafer, and
each of the tension members comprises: a shaft having an upper end locked by the face plate and a lower end penetrating the base plate; and a biasing unit that is positioned on the base plate and biases the lower end of the shaft downward.
